(19) United States
(12) Patent Application Publication
(10) Pub. No.: US 2026/0262173 A1
(43) Pub. Date: Sep. 3, 2026

(54) DISPLAY MODULE AND ELECTRONIC DEVICE INCLUDING THE SAME

(71) Applicant: Samsung Display Co., LTD., Yongin-si (KR)

(72) Inventors: DONGHWAN KIM, Yongin-si (KR); JUNGHOON SHIN, Yongin-si (KR); JUNWOO YOU, Yongin-si (KR); CHANGMOO LEE, Yongin-si (KR)

(21) Appl. No.: 19/533,912

(22) Filed: Feb. 9, 2026

(30) Foreign Application Priority Data
Feb. 28, 2025 (KR) 10-2025-0026692
Jun. 26, 2025 (KR) 10-2025-0084996

(51) Int. Cl. H05K 5/02

(52) U.S. Cl. CPC H05K 5/02

(57) ABSTRACT

A display module includes a display panel, a protective layer which is disposed under the display panel and includes ultrahigh molecular weight polyethylene, and a functional layer which is disposed under the protective layer and includes a heat radiating material. The protective layer has a horizontal thermal conductivity of about 1 W/m·K to about 150 W/m·K. The protective layer has a modulus of about 10 GPa to about 120 GPa.

This application claims priority to Korean Patent Application No. 10-2025-0026692, filed on Feb. 28, 2025, and Korean Patent Application No. 10-2025-0084996, filed on Jun. 26, 2025, and all the benefits accruing therefrom under 35 U.S.C. § 119, the contents of which in their entireties are herein incorporated by reference.

### BACKGROUND

### (1) Field

Embodiments of the present disclosure described herein relate to a display module and an electronic device including the display module, and more particularly, relate to a display module with reduced thickness and improved heat radiating characteristics and an electronic device including the display module.

### (2) Description of the Related Art

An electronic device, such as a smart phone, a digital camera, a notebook computer, a car navigation device, or a smart television, typically provides an image to a user through a display screen. The electronic device may include a display panel that generates the image. In recent years, with the development of various types of high-performance and compact electronic devices, high-capacity and high-integration electronic components are embedded therein.

### SUMMARY

In a high-performance and compact electronic device, a large amount of heat is generated from components thereof. The heat generated in the electronic device may reduce the lifetimes of the products or may cause a failure or malfunction in the components. Accordingly, methods for releasing the heat generated in an electronic device to the outside are being studied.

Embodiments of the present disclosure provide a display module and an electronic device having a small thickness and high heat radiating characteristics by employing a panel lower-portion protecting layer including ultrahigh molecular weight polyethylene.

According to an embodiment, a display module includes a display panel, a protective layer disposed under the display panel, where the protective layer includes ultrahigh molecular weight polyethylene, and a functional layer disposed under the protective layer, where the functional layer includes a heat radiating material.

In an embodiment, the protective layer may have a thickness of about 10 micrometers (μm) to about 50 μm.

In an embodiment, the protective layer may be a polymer film stretched in at least one direction.

In an embodiment, the protective layer may have a horizontal thermal conductivity of about 1 watt per meter kelvin (W/m·K) to about 150 W/m·K.

In an embodiment, the protective layer may have a modulus of about 10 gigapascals (GPa) to about 120 GPa.

In an embodiment, the protective layer may have a draw ratio of about 10 to about 250.

In an embodiment, the heat radiating material may include at least one selected from a thermally conductive metal, a carbon-based heat radiating material, and a thermally conductive polymer.

In an embodiment, the functional layer may further include a light blocking material.

In an embodiment, the light blocking material may include at least one selected from a carbon-based material, a black pigment, and a black dye, where the carbon-based material includes graphene or graphite.

In an embodiment, the functional layer may further include a foaming agent or elastic hollow particles.

In an embodiment, the display module may further include a first adhesive layer disposed between the protective layer and the display panel and a second adhesive layer disposed between the protective layer and the functional layer.

In an embodiment, the first adhesive layer may be disposed directly on the protective layer, the protective layer may be disposed directly on the second adhesive layer, and the second adhesive layer may be disposed directly on the functional layer.

In an embodiment, the heat radiating material may include a thermally conductive metal, and the thermally conductive metal may include at least one selected from copper (Cu), aluminum (Al), and stainless steel (SUS).

In an embodiment, the functional layer may be formed of the thermally conductive metal.

In an embodiment, the functional layer may have a thickness of about 10 μm to about 100 μm.

In an embodiment, the display module may further include a first adhesive layer disposed between the protective layer and the display panel. In such an embodiment, the protective layer may be disposed directly on the functional layer, and the first adhesive layer may be disposed directly on the protective layer.

According to an embodiment, an electronic device includes a display module which generates an image and a power module which supplies power to the display module. In such an embodiment, the display module includes a display panel, a protective layer disposed under the display panel, where the protective layer includes ultrahigh molecular weight polyethylene, and a functional layer disposed under the protective layer, where the functional layer includes a heat radiating material.

In an embodiment, the functional layer may further include a base resin, a light blocking material, and a foaming agent, and the heat radiating material, the light blocking material, and the foaming agent may be dispersed in the base resin.

In an embodiment, the heat radiating material may include at least one selected from copper (Cu), aluminum (Al), and stainless steel (SUS), and the functional layer may have a thickness of about 10 μm to about 100 μm.

In an embodiment, the protective layer may have a transmittance of about 90% or greater for light having a center wavelength of about 400 nm to about 700 nm.

### BRIEF DESCRIPTION OF THE DRAWINGS

The above and other features of embodiments of the present disclosure will become apparent by describing in detail embodiments thereof with reference to the accompanying drawings.

FIG. 1 is a block diagram of an electronic device according to an embodiment of the present disclosure.

FIG. 2 illustrates schematic views of electronic devices according to embodiments of the present disclosure.

FIG. 3 is a perspective view of the electronic device according to an embodiment of the present disclosure.

FIG. 4 is an exploded perspective view of the electronic device according to an embodiment of the present disclosure.

FIG. 5 is a sectional view of the electronic device according to an embodiment of the present disclosure.

FIG. 6 is a sectional view of a display panel according to an embodiment of the present disclosure.

FIG. 7A is a sectional view of a display module according to an embodiment of the present disclosure.

FIG. 7B is a sectional view illustrating a protective layer according to an embodiment of the present disclosure.

FIG. 8 is a sectional view of a display module according to an embodiment of the present disclosure.

FIG. 9 is a graph depicting a change in modulus and thermal conductivity depending on the draw ratio of the protective layer according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, when a component (or, an area, a layer, a part, etc.) is referred to as being “connected to” or “coupled to” another component, this means that the component may be directly connected to, or coupled to the other component or a third component may be present therebetween.

Identical reference numerals refer to identical components. Additionally, in the drawings, the thicknesses, proportions, and dimensions of components are exaggerated for effective description.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

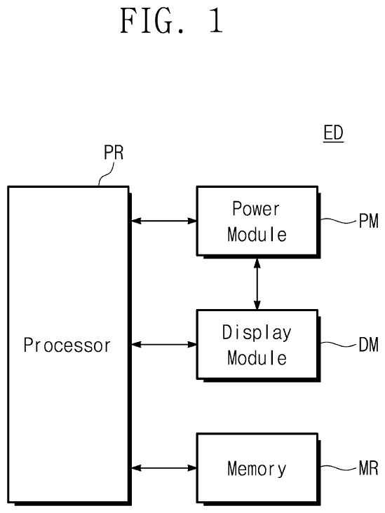

FIG. 1 is a block diagram of an electronic device according to an embodiment. Referring to FIG. 1, the electronic device ED according to an embodiment may include a display module DM, a processor PR, a memory MR, and a power module PM.

The processor PR may include at least one selected from a central processing unit (CPU), an application processor (AP), a graphic processing unit (GPU), a communication processor (CP), an image signal processor (ISP), and a controller.

Data information used for operation of the processor PR or the display module DM may be stored in the memory MR. When the processor PR executes an application stored in the memory MR, an image data signal and/or an input control signal may be transferred to the display module DM, and the display module DM may process the provided signal and may output image information through a display screen. The display module DM may include a display panel that displays an image.

The power module PM may include a power supply module, such as a power adapter or a battery device, and a power conversion module that converts power supplied by the power supply module and generates power used for operation of the electronic device ED.

At least one of the components of the electronic device ED described above may be included in a display device including a display module according to embodiments to be described below. In addition, some of the separate modules functionally included in one module may be included in the display device, and the others may be provided separately from the display device. In an embodiment, for example, the display device may include the display module DM, and the processor PR, the memory MR, and the power module PM may be provided in the form of other devices in the electronic device ED rather than the display device.

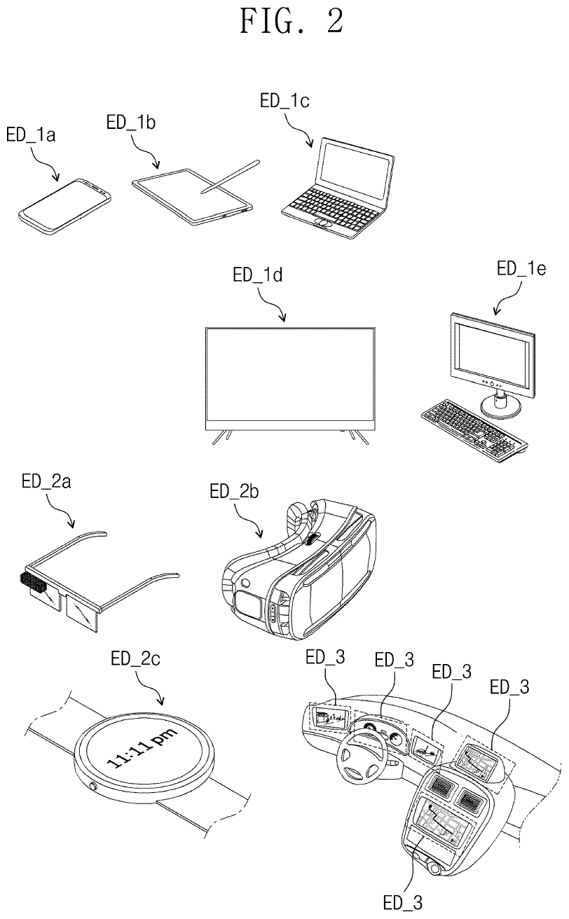

FIG. 2 illustrates schematic views of electronic devices according to various embodiments.

Referring to FIG. 2, various electronic devices including a display device according to an embodiment may include not only electronic devices for displaying images, such as a smart phone ED_1a, a tablet personal computer (PC) ED_1b, a laptop computer ED_1c, a television (TV) ED_1d, and a desk monitor ED_1e, but also wearable electronic devices, such as smart glasses ED_2a, a head mounted display ED_2b, and a smart watch ED_2c, and vehicle electronic devices ED_3, such as center information displays (CID) disposed on an instrument panel, a center fascia, and a dashboard of a vehicle and a room mirror display.

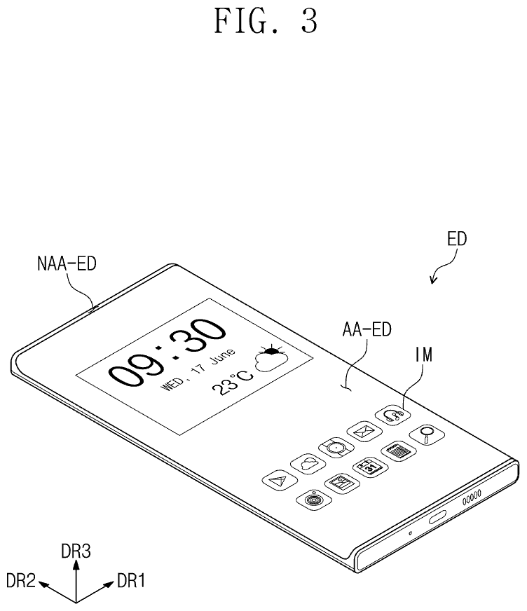

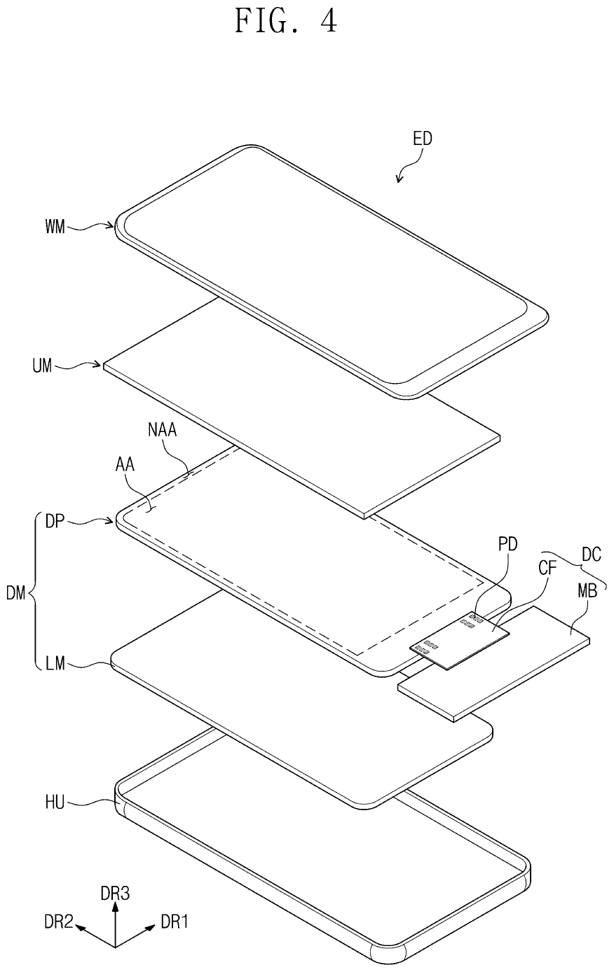

FIG. 3 is a perspective view of the electronic device ED according to an embodiment of the present disclosure. FIG. 4 is an exploded perspective view of the electronic device ED according to an embodiment of the present disclosure. FIG. 3 illustrates an embodiment where the electronic device ED is a mobile phone.

In an embodiment, the electronic device ED may display an image IM through an active area AA-DD. The active area AA-DD may include a plane defined by a first direction DR1 and a second direction DR2. The active area AA-DD may further include a curved plane bent from at least one side of the plane defined by the first direction DR1 and the second direction DR2. The electronic device ED according to an embodiment, as illustrated in FIG. 3, may include two curved planes bent from opposite sides of the plane defined by the first direction DR1 and the second direction DR2. However, the shape of the active area AA-DD is not limited thereto. In an embodiment, for example, the active area AA-DD may include only the plane. Alternatively, the active area AA-DD may further include curved planes bent from at least two sides of the plane, for example, four curved planes bent from four sides of the plane, respectively.

Although the first direction DR1, the second direction DR2, and a third direction DR3 are illustrated in FIG. 3 and the following drawings, the directions indicated by the first to third directions DR1, DR2, and DR3 described in this specification may be relative concepts and may be changed to other directions.

In this specification, the first direction DR1 and the second direction DR2 may be perpendicular to each other, and the third direction DR3 may be a normal direction to the plane defined by the first direction DR1 and the second direction DR2. The expression “from above the plane” or “in a plan view” used herein may mean that it is viewed from above the plane defined by the first direction DR1 and the second direction DR2, and a thickness direction may refer to the third direction DR3 that is a normal direction to the plane defined by the first direction DR1 and the second direction DR2.

The electronic device ED may include the active area AA-DD and a peripheral area NAA-DD adjacent to the active area AA-DD. The active area AA-DD may be a portion corresponding to a display area AA of a display panel DP to be described below, and the peripheral area NAA-DD may be a portion corresponding to a non-display area NAA of the display panel DP.

The peripheral area NAA-DD, which is an area that blocks an optical signal, may be disposed outside the active area AA-DD and may surround the active area AA-DD. In an embodiment, the peripheral area NAA-DD may be disposed on the lateral side rather than the frontside of the electronic device ED. In another embodiment, the peripheral area NAA-DD may be omitted.

The electronic device ED according to an embodiment may include a window WM, a housing HU, the display module DM, a circuit board DC, and an upper member UM.

The electronic device ED according to an embodiment may include the window WM disposed over the display panel DP. The window WM provides an outer surface of the electronic device ED. Although not illustrated, the window WM may include a base substrate and may further include functional layers such as an anti-reflective layer, an anti-fingerprint layer, and an optical layer that controls a phase.

In the electronic device ED according to an embodiment, the upper member UM may be disposed under the window WM and on the display module DM. The upper member UM may include an anti-reflective layer and an input detection sensor. The anti-reflective layer lowers the reflectance of external light. The input detection sensor senses an external input of a user. The upper member UM may further include an adhesive layer that couples the anti-reflective layer and the input detection sensor to each other.

In the electronic device ED according to an embodiment, the display module DM may be disposed under the upper member UM. The display module DM may include the display panel DP and a lower member LM.

In an embodiment, the display panel DP may include the display area AA where the image IM is displayed and the non-display area NAA adjacent to the display area AA. That is, the frontside of the display panel DP may include the display area AA and the non-display area NAA. The display area AA may be an area activated in response to an electrical signal.

The non-display area NAA may be adjacent to the display area AA. In an embodiment, the non-display area NAA may surround the display area AA in a plan view or when viewed in the third direction DR3. A driver circuit or driving wiring for driving the display area AA, various types of signal lines or pads for providing electrical signals to the display area AA, or electronic elements may be disposed in the non-display area NAA.

The display panel DP may include a light emitting element layer including an organic light emitting element, a quantum-dot light emitting element, a micro-light emitting diode (LED) light emitting element, or a nano-LED light emitting element. The light emitting element layer may be a component that substantially generates an image.

The electronic device ED may include the circuit board DC connected to the display panel DP. The circuit board DC may include a flexible board CF and a main board MB. The flexible board CF may include an insulating film and conductive wires mounted on the insulating film. The conductive wires are connected to pads PD and electrically connect the circuit board DC and the display panel DP. In another embodiment, the flexible board CF may be omitted. In such an embodiment, the main board MB may be directly connected to the display panel DP.

The main board MB may include non-illustrated signal lines and electronic elements. The electronic elements may be connected to the signal lines and may be electrically connected with the display panel DP. The electronic elements may generate various types of electrical signals, for example, a signal for generating the image IM or a signal for sensing an external input, or may process sensed signals. The main board MB may be provided in plural to correspond to electrical signals to be generated and processed and is not limited to any one embodiment.

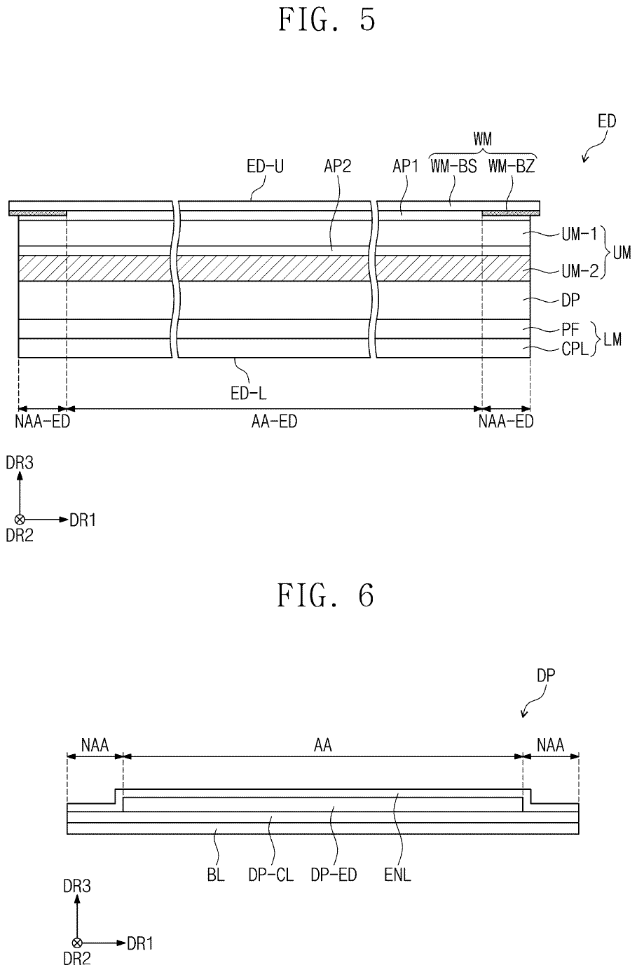

The lower member LM may be disposed under the display panel DP. The lower member LM may be a member that supports the display panel DP and performs a heat radiating function of releasing heat generated from the display panel DP. Detailed description of the lower member LM will be given blow with reference to FIG. 5 and the following drawings.

The electronic device ED according to an embodiment may include the housing HU disposed under the lower member LM. The display panel DP may be accommodated in the housing HU. In the electronic device ED according to an embodiment, the window WM and the housing HU may be coupled to form the exterior of the electronic device ED.

FIG. 5 is a sectional view illustrating some of the components of the electronic device ED according to an embodiment of the present disclosure.

Referring to FIG. 5, the electronic device ED according to an embodiment of the present disclosure may include the window WM, the upper member UM, the display panel DP, and the lower member LM. The electronic device ED may include a frontside ED-U and a backside ED-L. The frontside ED-U of the electronic device ED may be defined on the window WM, and the backside ED-L of the electronic device ED may be defined on the lower member LM.

In an embodiment, the window WM may cover a frontside (or a front surface) of the display panel DP. The window WM may include a base substrate WM-BS and a bezel pattern WM-BZ. The base substrate WM-BS includes a transparent base layer, which may be a glass substrate or a transparent film, for example. The bezel pattern WM-BZ may have a multi-layer structure. The multi-layer structure may include a colored layer and a black light-blocking layer. The colored layer and the black light-blocking layer may be formed through a deposition, printing, or coating process. The bezel pattern WM-BZ may be omitted from the window WM and may be formed on the upper member UM rather than the base substrate WM-BS.

In an embodiment, the upper member UM includes an anti-reflective layer UM-1 and an input sensor UM-2. In an embodiment, as illustrated in FIG. 5, the window WM and the anti-reflective layer UM-1 may be coupled through a first adhesive member AP1, and the anti-reflective layer UM-1 and the input sensor UM-2 may be coupled through a second adhesive member AP2. At least one selected from the first adhesive member AP1 and the second adhesive member AP2 may be omitted. In an embodiment, for example, the second adhesive member AP2 may be omitted, and the anti-reflective layer UM-1 may be disposed directly on the input sensor UM-2.

The anti-reflective layer UM-1 may lower the reflectance of external light. The anti-reflective layer UM-1 may include a phase retarder and/or a polarizer. The anti-reflective layer UM-1 may include a polarizer film and color filters. The color filters may have a certain arrangement. The arrangement of the color filters may be determined in consideration of emission colors of pixels included in the display panel DP. The anti-reflective layer UM-1 may further include a split layer adjacent to the color filters.

The input sensor UM-2 may include a plurality of sensing electrodes (not illustrated) for sensing an external input, trace lines (not illustrated) that are connected to the plurality of sensing electrodes, and an inorganic layer and/or an organic layer for insulating/protecting the plurality of sensing electrodes or the trace lines. In an embodiment, for example, the input sensor UM-2 may be a capacitive sensor, but is not particularly limited.

In an embodiment, the input sensor UM-2 may be directly formed on a thin film encapsulation layer when the display panel DP is manufactured. In another embodiment, without being limited thereto, the input sensor UM-2 may be manufactured as a panel separate from the display panel DP and may be attached to the display panel DP by an adhesive layer.

The lower member LM may include a protective layer PF and a functional layer CPL. The protective layer PF may be disposed under the display panel DP, and the functional layer CPL may be disposed under the protective layer PF.

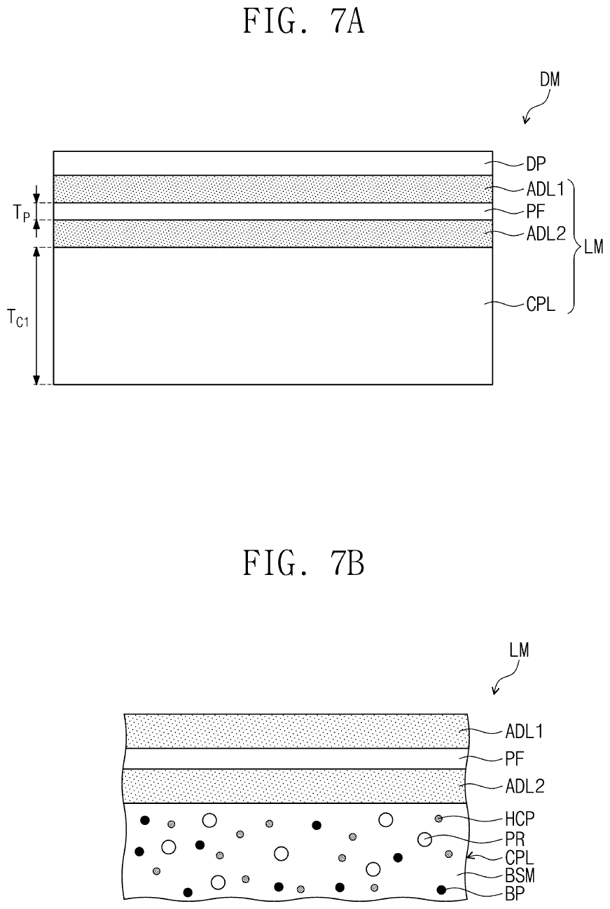

The protective layer PF may be a component that supports the display panel DP and increases resistance to a compressive force due to external pressing to increase the resistance of the display panel DP. In addition, the protective layer PF may have high thermal conductivity and may serve to effectively release heat generated from the electronic device ED. The protective layer PF may include ultrahigh molecular weight polyethylene and thus may have high thermal conductivity. Accordingly, the protective layer PF may exhibit a high heat radiating effect even without a separate heat radiating material. Detailed description of the protective layer PF will be given blow with reference to FIG. 7A and the following drawings.

The functional layer CPL may be a component that is disposed under the protective layer PF and that absorbs impact applied to the display panel DP and releases heat generated from the components disposed under the display panel DP. The functional layer CPL includes a heat radiating material. The functional layer CPL, which includes the heat radiating material, may effectively release heat generated from the electronic device ED. Detailed description of the functional layer CPL will be given blow with reference to FIG. 7A and the following drawings.

FIG. 6 is a sectional view of the display panel DP according to an embodiment.

In an embodiment, the display panel DP may include a base layer BL, and a circuit layer DP-CL, a light emitting element layer DP-ED, and an encapsulation layer ENL that are disposed on the base layer BL.

The base layer BL may include a plastic substrate, a glass substrate, a metal substrate, or an organic/inorganic composite substrate. In an embodiment, for example, the base layer BL may include at least one polyimide layer. The above-described lower member LM may be disposed under the base layer BL.

The circuit layer DP-CL includes at least one insulating layer, semiconductor patterns, and conductive patterns. The insulating layer includes at least one inorganic layer and at least one organic layer. The semiconductor patterns and the conductive patterns may constitute signal lines, a pixel driver circuit, and a scan driver circuit. In an embodiment, the circuit layer DP-CL may further include a backside metal layer.

The light emitting element layer DP-ED includes a display element, for example, a light emitting element. In an embodiment, for example, the light emitting element may be an organic light emitting element, a quantum-dot light emitting element, a micro-LED light emitting element, or a nano-LED light emitting element. The light emitting element layer DP-ED may further include an organic layer such as a pixel defining layer.

The light emitting element layer DP-ED may be disposed in the display area AA. The non-display area NAA may be disposed outside the display area AA and may surround the display area AA. A light emitting element may not be disposed in the non-display area NAA.

The encapsulation layer ENL may be disposed on the light emitting element layer DP-ED and may cover the light emitting element layer DP-ED. The encapsulation layer ENL may be disposed on the circuit layer DP-CL to seal the light emitting element layer DP-ED. The encapsulation layer ENL may be a thin film encapsulation layer including a plurality of organic thin films and a plurality of inorganic thin films. The encapsulation layer ENL may include a thin film encapsulation layer including a stack structure of an inorganic layer/an organic layer/an inorganic layer. The stack structure of the encapsulation layer ENL is not particularly limited.

FIG. 7A is a sectional view of the display module DM according to an embodiment of the present disclosure. FIG. 7B is a sectional view illustrating the protective layer PF according to an embodiment of the present disclosure.

Referring to FIG. 7A, the display module DM according to an embodiment of the present disclosure may include the display panel DP and the lower member LM disposed under the display panel DP. The display module DM may be constituted by the display panel DP and the lower member LM. In an embodiment, the lower member LM may be disposed directly under the display panel DP.

The lower member LM may include the protective layer PF disposed under the display panel DP and the functional layer CPL disposed under the protective layer PF.

In an embodiment, the protective layer PF may include ultrahigh molecular weight polyethylene. The protective layer PF may be a polymer film including ultrahigh molecular weight polyethylene. The protective layer PF may be a polymer film including or formed of ultrahigh molecular weight polyethylene.

The protective layer PF may be a polymer film stretched in at least one direction. That is, the ultrahigh molecular weight polyethylene constituting the protective layer PF may be stretched in at least one direction. The ultrahigh molecular weight polyethylene included in the protective layer PF may include crystalline polymers arranged in at least one direction. The protective layer PF may be an ultrahigh molecular weight polyethylene film stretched in at least one direction.

The protective layer PF may be a uniaxially or biaxially stretched film. The protective layer PF may be a uniaxially stretched film stretched by a predetermined amount in a machine direction MD or a transverse direction TD or may be a biaxially stretched film stretched by a predetermined amount in each of the machine direction MD and the transverse direction TD.

In an embodiment, the protective layer PF may be a uniaxially stretched film stretched in one direction. The ultrahigh molecular weight polyethylene included in the protective layer PF may be stretched in the one direction. The ultrahigh molecular weight polyethylene stretched in the one direction may include crystalline polymers oriented in the one direction. In an embodiment where the ultrahigh molecular weight polyethylene is stretched in the one direction, the crystalline polymers included in the ultrahigh molecular weight polyethylene may be oriented in the stretched direction. The ultrahigh molecular weight polyethylene stretched in the one direction may have high thermal conductivity characteristics. By orienting the crystalline polymers included in the ultrahigh molecular weight polyethylene in the one direction through a stretching process, the degree of orientation of the crystalline polymers may be increased, and accordingly heat may be rapidly conducted in the direction of the orientation axis. Thus, high thermal conductivity characteristics may be implemented.

In an embodiment, the thickness T_{P} of the protective layer PF may be in a range from about 10 micrometers (μm) to about 50 μm. When the thickness T_{P} of the protective layer PF is less than about 10 μm, the heat radiating function of the protective layer PF may be deteriorated, and the function of protecting the display panel from external impact may be deteriorated. When the thickness T_{P} of the protective layer PF exceeds about 50 μm, the overall thickness of the display module DM may be increased, and therefore it may be difficult to make the display module DM thinner in thickness. When the thickness T_{P} of the protective layer PF satisfies the above-described range, the protective layer PF may have high impact resistance while exhibiting high heat radiating characteristics. In addition, the overall thickness of the display module DM may be reduced, and thus the electronic device ED (refer to FIG. 5) may be allowed to be thinner in thickness.

In an embodiment, the protective layer PF may have a transmittance of about 90% or greater for light having a center wavelength of about 400 nanometers (nm) to about 700 nm. The protective layer PF may have a high transmittance of about 90% or greater in a visible light range of about 400 nm to about 700 nm.

In an embodiment, the horizontal thermal conductivity of the protective layer PF may be in a range from about 1 watt per meter kelvin (W/m·K) to about 150 W/m·K. In such an embodiment, where the protective layer PF has a high horizontal thermal conductivity of 1 W/m·K to 150 W/m·K, heat generated from the electronic device ED (refer to FIG. 5) may be effectively released.

The modulus (e.g., Young's modulus) of the protective layer PF at a room temperature (e.g., about 25° C.) may be in a range from about 10 gigapascals (GPa) to 120 about GPa. When the modulus of the protective layer PF is less than about 10 GPa, a strength sufficient to protect the display panel DP may not be secured, and therefore impact resistance characteristics may be deteriorated. Since the protective layer PF has a high modulus of about 10 GPa to about 120 GPa, the protective layer PF may exhibit a strength sufficient to protect the display panel. That is, when the modulus of the protective layer PF satisfies the above-described range, the protective layer PF may secure dimensional stability against an external force and may exhibit a strength sufficient to protect the display panel DP.

In an embodiment, the draw ratio of the protective layer PF under the temperature condition of about 120° C. to about 130° C. may be in a range from about 10 to about 250. The draw ratio of the protective layer PF in the machine direction MD and the draw ratio of the protective layer PF in the transverse direction TD may each range from 10 to 250. When the draw ratio of the protective layer PF is less than 10, the crystalline polymers may not be sufficiently oriented, and therefore it may be difficult to implement desired thermal conductivity characteristics. When the draw ratio of the protective layer PF exceeds 250, breakage may occur during stretching, and the shrinkage rate of the stretched polymer film may be increased so that durability may be deteriorated. In an embodiment, as described above, the protective layer PF has a draw ratio of about 10 to about 250 under the temperature condition of about 120° C. to about 130° C., such that the degree of orientation of the crystalline polymers may be increased. Accordingly, the protective layer PF may have high thermal conductivity and thus may exhibit high heat radiating characteristics. In this specification, the term “draw ratio” means the ratio of the length of the polymer film after stretching to the length of the polymer film before stretching, and the length of the polymer film may be measured at a room temperature (e.g., about 25° C.).

FIG. 9 is a graph depicting a change in modulus and thermal conductivity depending on the draw ratio of the protective layer according to an embodiment. In FIG. 9, the horizontal axis of the graph represents the draw ratio, and the vertical axis of the graph represents the modulus and the thermal conductivity. The graph illustrated in FIG. 9 depicts results obtained by measuring the modulus and the thermal conductivity changing depending on the draw ratio when the protective layer constituted by the ultrahigh molecular weight polyethylene film is uniaxially stretched. In FIG. 9, the thermal conductivity corresponds to the thermal conductivity in the horizontal direction.

Referring to FIG. 9, it can be seen that both the modulus and the thermal conductivity of the protective layer are improved as the draw ratio is increased. The degree of orientation of the crystalline polymers included in the ultrahigh molecular weight polyethylene may be increased as the draw ratio is increased. Accordingly, the ultrahigh molecular weight polyethylene film with an increased draw ratio may have high rigidity and may have high thermal conductivity above a predetermined level. The protective layer PF according to an embodiment that has a high draw ratio of about 10 to about 250 may exhibit a high modulus of about 10 GPa to about 120 GPa and a high thermal conductivity of about 1 W/m·K to about 150 W/m·K.

Referring back to FIGS. 7A and 7B, the functional layer CPL may be disposed under the display panel DP. The functional layer CPL may be disposed under the protective layer PF. The functional layer CPL may be spaced apart from the display panel DP with the protective layer PF therebetween. In an embodiment, the thickness T_{C1} of the functional layer CPL may be in a range from about 50 μm to about 300 μm. In an embodiment, for example, the thickness T_{C1} of the functional layer CPL may be in a range from about 100 μm to about 200 μm.

The functional layer CPL may include a heat radiating material HCP. The heat radiating material HCP included in the functional layer CPL may include, for example, at least one selected from a thermally conductive metal, a carbon-based heat radiating material, and a thermally conductive polymer.

The heat radiating material HCP included in the functional layer CPL may include a thermally conductive metal such as copper (Cu), aluminum (Al), silver (Ag), magnesium (Mg), or stainless steel (SUS). The functional layer CPL may include at least one selected from copper (Cu), aluminum (Al), silver (Ag), magnesium (Mg), and stainless steel (SUS).

Alternatively, the heat radiating material HCP included in the functional layer CPL may include a carbon-based material such as graphene, graphite, or carbon nanotubes. In another embodiment, the heat radiating material HCP included in the functional layer CPL may include a thermally conductive polymer.

The functional layer CPL may further include a light blocking material BP. The functional layer, which includes the light blocking material BP, may have a black color. The light blocking material BP included in the functional layer CPL may be, for example, a black pigment or a black dye. Alternatively, the light blocking material BP included in the functional layer CPL may be a carbon-based material such as graphene or graphite. In an embodiment where the functional layer CPL includes the light blocking material BP, the functional layer CPL may block light emitted from the display panel DP from being leaked below the display panel DP. In such an embodiment, the functional layer CPL may not only protect the display panel DP from external impact, but may also perform a blocking function of blocking light emitted from the display panel DP. Accordingly, the functional layer CPL included in the electronic device ED (refer to FIG. 5) according to an embodiment may not include a separate light blocking sheet. Since the functional layer CPL does not include a separate light blocking sheet, the thickness of the functional layer may be reduced. Accordingly, the electronic device ED (refer to FIG. 5) may be allowed to be lighter in weight and thinner in thickness.

The functional layer CPL may further include at least one selected from a foaming agent PR and elastic hollow particles. In an embodiment, for example, the functional layer CPL may further include the foaming agent PR. In such an embodiment where the foaming agent PR or the elastic hollow particles are included in the functional layer, the impact absorbing characteristics of the functional layer CPL may be improved. In a case where the functional layer CPL includes a particle-type additive such as the heat radiating material HCP, the impact absorbing characteristics of the functional layer CPL may be deteriorated. However, the functional layer CPL according to an embodiment may include the foaming agent or the elastic hollow particles for absorbing impact, and thus the deterioration in the impact absorbing characteristics of the functional layer CPL may be prevented.

In an embodiment, the functional layer CPL may further include a material having a shielding function. The functional layer CPL may further include an electromagnetic shielding material. In such an embodiment where the functional layer CPL includes the electromagnetic shielding material, an electric field and a magnetic field generated from electronic components disposed under the functional layer CPL may be effectively prevented from being transferred to the display panel DP over the functional layer CPL.

The functional layer CPL may further include a base resin BSM. The base resin BSM may include at least one selected from an acrylic resin, a urethane-based resin, a fluorine-based resin, an epoxy resin, a polyester resin, a polyamide resin, and a silicone resin. The functional layer CPL may further include an additive. The additive may be a thermal initiator or a photo-initiator, for example.

In an embodiment, the functional layer CPL may include the base resin BSM, and the heat radiating material HCP, the light blocking material BP, and the foaming agent PR that are dispersed in the base resin BSM. In such an embodiment where the functional layer CPL includes the base resin BSM, the heat radiating material HCP, the light blocking material BP, and the foaming agent PR, the functional layer CPL may perform multiple functions in the electronic device. In an embodiment, for example, the functional layer CPL may support the display panel DP. The functional layer CPL may protect the display panel DP from physical impact applied from the outside. In addition, the functional layer CPL may perform a heat radiating function of releasing heat generated from the display panel DP. The functional layer CPL may also perform a light blocking function of blocking light emitted from the display panel DP. However, without being limited thereto, and depending on the characteristics such as the material included in the functional layer CPL and the thickness thereof, the functional layer CPL may additionally perform other functions in the electronic device ED. In an embodiment, for example, the functional layer CPL may further include a material having a shielding function. In such an embodiment where the functional layer CPL includes the electromagnetic shielding material, the functional layer CPL may have an electromagnetic shielding function.

The functional layer CPL may be a member that is disposed under the display panel DP and that integrally has various functions for protecting the display panel DP. In an embodiment, for example, the functional layer CPL may simultaneously perform a heat radiating function, an impact absorbing function, and a light blocking function. In addition, the functional layer CPL may further perform a shielding function as desired.

The functional layer CPL may include a plurality of materials to perform the above-described functions. In an embodiment, for example, the functional layer CPL may include the heat radiating material HCP, an impact absorbing material such as the foaming agent PR or the elastic hollow particles, and the light blocking material BP. In addition, the functional layer CPL may further include the electromagnetic shielding material as desired.

The functional layer CPL may be formed in various ways. The functional layer CPL may be formed by at least one selected from a spin coating method, a slit coating method, a jet printing method, a metal mask printing method, and a screen printing method. In an embodiment, for example, the functional layer CPL may be formed by the screen printing method.

The lowermost side of the display module DM may be defined as the lower side of the functional layer CPL. Accordingly, the thickness of the electronic device ED according to an embodiment may be reduced, components may be simplified, and the electronic device ED may be allowed to be thinner in thickness.

The display module DM may further include a first adhesive layer ADL1 disposed between the display panel DP and the protective layer PF. The first adhesive layer ADL1 may couple the display panel DP and the protective layer PF. The upper side of the first adhesive layer ADL1 may make contact with the display panel DP, and the lower side of the first adhesive layer ADL1 may make contact with the protective layer PF.

The display module DM may further include a second adhesive layer ADL2 disposed between the protective layer PF and the functional layer CPL. The second adhesive layer ADL2 may couple the protective layer PF and the functional layer CPL. The upper side of the second adhesive layer ADL2 may make contact with the protective layer PF, and the lower side of the second adhesive layer ADL2 may make contact with the functional layer CPL.

Each of the first adhesive layer ADL1 and the second adhesive layer ADL2 may be a pressure sensitive adhesive film (PSA) or an optically clear adhesive (OCA).

The display module DM according to an embodiment may include the protective layer PF disposed under the display panel DP and the functional layer CPL disposed under the protective layer PF. In addition, the display module DM may include the first adhesive layer ADL1 disposed between the display panel DP and the protective layer PF and the second adhesive layer ADL2 disposed between the protective layer PF and the functional layer CPL. In the display module DM according to an embodiment, the second adhesive layer ADL2 may be disposed directly on the functional layer CPL, the protective layer PF may be disposed directly on the second adhesive layer ADL2, and the first adhesive layer ADL1 may be disposed directly on the protective layer PF. However, embodiments are not limited thereto, and either the first adhesive layer ADL1 or the second adhesive layer ADL2 may be omitted.

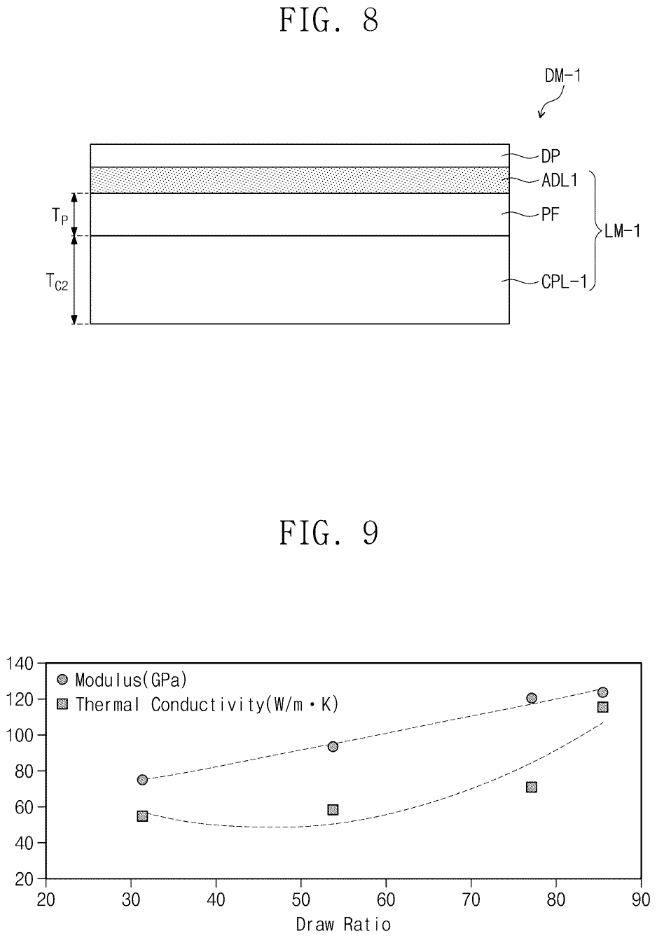

FIG. 8 is a sectional view of a display module DM-1 according to an embodiment of the present disclosure.

The display module DM-1 of the embodiment illustrated in FIG. 8 substantially the same as the display module DM of the embodiment illustrated in FIG. 7A except that a functional layer CPL-1 includes a thermally conductive metal as a heat radiating material and a protective layer PF is disposed directly on the functional layer CPL-1.

The display module DM-1 according to an embodiment may include a display panel DP and a lower member LM-1 disposed under the display panel DP. The lower member LM-1 may include the protective layer PF disposed under the display panel DP and the functional layer CPL-1 disposed under the protective layer PF.

The display module DM-1 according to an embodiment may further include a first adhesive layer ADL1 disposed between the display panel DP and the protective layer PF. The first adhesive layer ADL1 may couple the display panel DP and the protective layer PF. The upper side of the first adhesive layer ADL1 may make contact with the display panel DP, and the lower side of the first adhesive layer ADL1 may make contact with the protective layer PF. The first adhesive layer ADL1 may be a pressure sensitive adhesive film (PSA) or an optically clear adhesive (OCA).

The protective layer PF may be disposed directly on the functional layer CPL-1. The lower side of the protective layer PF may make contact with the functional layer CPL-1. The protective layer PF may be disposed directly on the functional layer CPL-1, and the first adhesive layer ADL1 may be disposed directly on the protective layer PF.

In an embodiment, the functional layer CPL-1 may include a thermally conductive metal, such as copper (Cu), aluminum (Al), silver (Ag), magnesium (Mg), or stainless steel (SUS), as a heat radiating material. The functional layer CPL-1 may include at least one selected from copper (Cu), aluminum (Al), silver (Ag), magnesium (Mg), and stainless steel (SUS).

In an embodiment, the functional layer CPL-1 may be formed of a thermally conductive metal. The functional layer CPL-1 may be formed of at least one metal selected from copper (Cu), aluminum (Al), silver (Ag), magnesium (Mg), and stainless steel (SUS). In such an embodiment where the functional layer CPL-1 is formed of a thermally conductive metal, the functional layer CPL-1 may exhibit sufficient impact absorbing characteristics and electromagnetic shielding characteristics even without a separate impact absorbing material and a separate shielding material. Thus, the functional layer CPL-1 may be allowed to be thinner in thickness.

In an embodiment, the functional layer CPL-1 may be directly formed on one side of the protective layer PF. In an embodiment, for example, the functional layer CPL-1 may be formed by plating the one side of the protective layer PF with a thermally conductive metal. The functional layer CPL-1 may be formed by plating the one side of the protective layer PF with a thermally conductive metal such as copper (Cu), aluminum (Al), silver (Ag), or magnesium (Mg).

The thickness T_{C2} of the functional layer CPL-1 included in the display module DM-1 illustrated in FIG. 8 may be smaller than the thickness T_{C1} of the functional layer CPL included in the display module DM illustrated in FIG. 7A. In an embodiment, the thickness T_{C2} of the functional layer CPL-1 included in the display module DM-1 according to an embodiment may be in a range from about 10 μm to about 100 μm. That is, the thickness T_{C2} of the metal formed on the one side of the protective layer PF through the plating process may have a small thickness of about 10 μm to about 100 μm. When the thickness T_{C2} of the functional layer CPL-1 is less than 10 μm, heat radiating characteristics, shielding characteristics, and impact resistance characteristics through the functional layer CPL-1 may be deteriorated. By adjusting the thickness T_{C2} of the functional layer CPL-1 to about 10 μm or greater and about 100 μm or less, the functional layer CPL-1 may be allowed to be thin while implementing sufficient heat radiating characteristics, shielding characteristics, and impact resistance characteristics. Accordingly, the reliability of the display module DM-1 may be improved, and a thickness reduction effect may be maximized.

In an embodiment, the protective layer PF may include ultrahigh molecular weight polyethylene. The protective layer PF may be a polymer film including ultrahigh molecular weight polyethylene. The protective layer PF may be a polymer film formed of ultrahigh molecular weight polyethylene.

In an embodiment, the protective layer PF may be a polymer film stretched in at least one direction. That is, the ultrahigh molecular weight polyethylene constituting the protective layer PF may be stretched in at least one direction. The ultrahigh molecular weight polyethylene included in the protective layer PF may include crystalline polymers arranged in at least one direction. The protective layer PF may be an ultrahigh molecular weight polyethylene film stretched in at least one direction.

In such an embodiment where the protective layer PF includes the ultrahigh molecular weight polyethylene film stretched in at least one direction, the protective layer PF may exhibit high heat radiating characteristics and high impact resistance characteristics. Due to the protective layer PF having high heat radiating characteristics and impact resistance characteristics, the thickness of the functional layer CPL-1 may be reduced, and thus the electronic device ED may be made thinner in thickness.

In order to secure sufficient heat radiating characteristics, the horizontal thermal conductivity of a heat dissipating material has to be above a predetermined level. However, when a thermally conductive metal is applied to a functional layer as a heat radiating material, heat radiating characteristics may be secured due to the high thermal conductivity of the metallic material. However, since the thickness and thermal conductivity of the metal have a direct proportional relationship, the thermal conductivity characteristics decrease when the thickness of the metal decreases, so that there is a limitation in making the functional layer thinner in thickness.

Table 1 below shows the horizontal thermal conductivities measured depending on a change in the thickness of aluminum (Al) that is a thermally conductive metal. Referring to Table 1 below, it can be seen that the horizontal thermal conductivity is lowered as the thickness of aluminum decreases. Accordingly, it can be seen that in order to secure sufficient heat radiating characteristics by applying the thermally conductive metal to the functional layer, the thermally conductive metal has to have a thickness above a predetermined level. That is, there is a problem that it is not easy to implement a functional layer that exhibits sufficient heat radiating characteristics while having a small thickness.

TABLE 1

| | | |
|---|---|---|
| Thermally Conductive Metal | Al (100 μm) | Al (38 μm) |
| Thickness) | | |
| Horizontal Thermal Conductivity | 131.3 | 26.8 |
| (W/m·K) | | |

In embodiments of the present disclosure, by applying ultrahigh molecular weight polyethylene to the lower protective layer PF disposed under the display panel DP, the protective layer PF itself may exhibit heat radiating characteristics. Accordingly, even though the thickness of the functional layer CPL-1 is decreased, deterioration in the heat radiating performance of the electronic device may be effectively prevented. Since the ultrahigh molecular weight polyethylene included in the lower protective layer PF is stretched in at least one direction, the ultrahigh molecular weight polyethylene may have highly oriented polymer crystals and thus may exhibit high horizontal thermal conductivity characteristics. Accordingly, deterioration in the heat radiating performance of the electronic device due to a decrease in the thickness of the functional layer CPL-1 may be prevented by imparting heat radiating characteristics to the protective layer PF. Due to the protective layer PF having heat radiating characteristics by itself, the thickness of the functional layer CPL-1 may be reduced, and thus the electronic device ED may be made thinner in thickness.

Hereinafter, a protective layer and a display module including the same will be described in more detail through an embodiment and a comparative example. However, the embodiment and the comparative example to be described below are only examples for explaining the present disclosure in more detail, and the present disclosure is not limited by the embodiment and the comparative example to be described below.

### 1. Evaluation of Physical Properties of Protective Layers

Table 2 below shows the horizontal thermal conductivities, the moduli, and the transmittances of protective layers according to the embodiment and the comparative example. In the embodiment, an ultrahigh molecular weight polyethylene (UHMWPE) film is used as a protective layer, and in the comparative example, a polyethylene terephthalate (PET) film is used as a protective layer.

TABLE 2

| Classification | Embodiment | Comparative Example |
|---|---|---|
| Material | UHMWPE | PET |
| Thickness (μm) | 10~20 | 75 |
| Horizontal Thermal | 1~150 | 0.24 |
| Conductivity (W/m·K) | | |
| Modulus (GPa) | 10~120 | 2.5~4 |
| Transmittance (%) | ≥90 | 93 |

Referring to Table 2, it can be seen that the protective layer of the embodiment that includes the ultrahigh molecular weight polyethylene film has a relatively small thickness and exhibits a high horizontal thermal conductivity and a high modulus value when compared to the protective layer of the comparative example that includes the polyethylene terephthalate film. Specifically, it can be seen that even though the protective layer of the embodiment has a thickness reduced by about 86% when compared to the protective layer of the comparative example, the protective layer of the embodiment exhibits a horizontal thermal conductivity about 625 times higher than the horizontal thermal conductivity of the protective layer of the comparative example and has a modulus value about 30 times higher than the modulus value of the protective layer of the comparative example. In addition, it can be seen that the protective layer of the embodiment has a high transmittance of about 90% or greater. The protective layer of the embodiment that includes the ultrahigh molecular weight polyethylene film may exhibit high heat radiating characteristics and high strength characteristics with a relatively small thickness when compared to the protective layer of the comparative example that includes the polyethylene terephthalate film. Accordingly, the protective layer of the embodiment may have an advantage in slimness, and due to the high heat radiating characteristics and the high strength characteristics of the protective layer, the parts of the functional layer disposed under the protective layer may be simplified and made thinner in thickness.

### 2. Manufacture and Evaluation of Display Modules

### (Manufacture of Embodiments 1 to 3)

Display modules including the stack structure illustrated in FIG. 7A are manufactured. Each of lower members included in Embodiments 1 to 3 includes a functional layer, a second adhesive layer, a protective layer, and a first adhesive layer sequentially stacked in a thickness direction as illustrated in FIG. 7A, and the protective layer includes an ultrahigh molecular weight polyethylene (UHMWPE) film. That is, the protective layers included in Embodiments 1 to 3 correspond to uniaxially stretched ultrahigh molecular weight polyethylene films. Embodiments 1 to 3 are the same as one another in terms of the thicknesses and materials of the stacked components, except that the protective layers have different moduli from each other. Embodiment 1 corresponds to the case in which the modulus of the protective layer is about 10 GPa, Embodiment 2 corresponds to the case in which the modulus of the protective layer is about 15 GPa, and Embodiment 3 corresponds to the case in which the modulus of the protective layer is about 25 GPa.

### (Manufacture of Comparative Example 1)

A display module is manufactured in the same manner as in Embodiments 1 to 3, except that a protective layer includes a polyethylene terephthalate (PET) film.

(Evaluation of Characteristics of Display modules)

Table 3 below shows evaluation results of the display modules of Embodiments 1 to 3 and Comparative Example 1 described above. Table 3 shows the strains of the display modules according to Embodiments 1 to 3 and Comparative Example 1. In Table 3, the modulus measurement values correspond to the moduli of the protective layers of the display modules according to Embodiments 1 to 3 and Comparative Example 1. The strains in Table 3 are obtained by measuring strains applied to back planes of display panels when a steel ball having a weight of about 2 g is dropped from a height of 10 cm onto the upper sides of the display modules. Here, the back planes may mean lower substrates of the panels that include a circuit layer.

TABLE 3

| | Embodiment | Embodiment | Embodiment | Comparative |
|---|---|---|---|---|
| Classification | 1 | 2 | 3 | Example 1 |
| Thickness (um) | 10 | 10 | 10 | 75 |
| Modulus (GPa) | 10 | 15 | 25 | 3.5 |
| Strain (%) | 0.449 | 0.426 | 0.385 | 0.45 |

Referring to the results in Table 3, it can be seen that the strains in Embodiments 1 to 3 are reduced when compared to that in Comparative Example 1. In the case of Comparative Example 1, it can be seen that the strain is about 0.45%, which is higher than those in Embodiments 1 to 3. Embodiments 1 to 3 in which the protective layers include stretched ultrahigh molecular weight polyethylene (UHMWPE) may have high moduli of about 10 GPa or greater and may exhibit low strains. Accordingly, the durability and reliability of a display device including a protective layer of an embodiment may be improved.

According to embodiments of the present disclosure, since the lower protective layer protecting the display panel includes the ultrahigh molecular weight polyethylene, the lower protective layer may exhibit high heat radiating characteristics and impact resistance characteristics, and thus the durability and reliability of the display module may be improved. In such embodiments, due to the lower protective layer having high heat radiating characteristics and impact resistance characteristics, the thickness of the functional layer may be reduced, and thus the electronic device may be allowed to be thinner in thickness.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module comprising:
a display panel;
a protective layer disposed under the display panel, wherein the protective layer includes ultrahigh molecular weight polyethylene; and
a functional layer disposed under the protective layer, wherein the functional layer includes a heat radiating material.

2. The display module of claim 1, wherein the protective layer has a thickness of about 10 μm to about 50 μm.

3. The display module of claim 1, wherein the protective layer is a polymer film stretched in at least one direction.

4. The display module of claim 1, wherein the protective layer has a horizontal thermal conductivity of about 1 W/m·K to about 150 W/m·K.

5. The display module of claim 1, wherein the protective layer has a modulus of about 10 GPa to about 120 GPa.

6. The display module of claim 1, wherein the protective layer has a draw ratio of about 10 to about 250.

7. The display module of claim 1, wherein the heat radiating material includes at least one selected from a thermally conductive metal, a carbon-based heat radiating material, and a thermally conductive polymer.

8. The display module of claim 1, wherein the functional layer further includes a light blocking material.

9. The display module of claim 8, wherein the light blocking material includes at least one selected from a carbon-based material, a black pigment, and a black dye, wherein the carbon-based material includes graphene or graphite.

10. The display module of claim 1, wherein the functional layer further includes a foaming agent or elastic hollow particles.

11. The display module of claim 1, further comprising:
a first adhesive layer disposed between the protective layer and the display panel; and
a second adhesive layer disposed between the protective layer and the functional layer.

12. The display module of claim 11, wherein the first adhesive layer is disposed directly on the protective layer,
wherein the protective layer is disposed directly on the second adhesive layer, and
wherein the second adhesive layer is disposed directly on the functional layer.

13. The display module of claim 1, wherein the heat radiating material includes a thermally conductive metal, and
wherein the thermally conductive metal includes at least one selected from copper (Cu), aluminum (Al), and stainless steel (SUS).

14. The display module of claim 13, wherein the functional layer is formed of the thermally conductive metal.

15. The display module of claim 13, wherein the functional layer has a thickness of about 10 μm to about 100 μm.

16. The display module of claim 13, further comprising:
a first adhesive layer disposed between the protective layer and the display panel,
wherein the protective layer is disposed directly on the functional layer, and
wherein the first adhesive layer is disposed directly on the protective layer.

17. An electronic device comprising:
a display module which generates an image; and
a power module which supplies power to the display module,
wherein the display module includes:
a display panel;
a protective layer disposed under the display panel, wherein the protective layer includes ultrahigh molecular weight polyethylene; and
a functional layer disposed under the protective layer, wherein the functional layer includes a heat radiating material.

18. The electronic device of claim 17, wherein the functional layer further includes a base resin, a light blocking material, and a foaming agent, and
wherein the heat radiating material, the light blocking material, and the foaming agent are dispersed in the base resin.

19. The electronic device of claim 17, wherein the heat radiating material includes at least one selected from copper (Cu), aluminum (Al), and stainless steel (SUS), and
wherein the functional layer has a thickness of about 10 μm to about 100 μm.

20. The electronic device of claim 17, wherein the protective layer has a transmittance of about 90% or greater for light having a center wavelength of about 400 nm to about 700 nm.
